(19) United States
(12) Patent Application Publication
(10) Pub. No.: US 2006/0141152 A1
(43) Pub. Date: Jun. 29, 2006

(54) CVD apparatus and manufacturing method of semiconductor device using the same

(75) Inventor: Jae-Young Oh, Chungcheongbuk-do (KR)

Correspondence Address: THE LAW OFFICES OF ANDREW D. FORTNEY, PH.D., P.C., 7257 N. MAPLE AVENUE, BLDG. D, SUITE 107, FRESNO, CA, 93720, US

(73) Assignee: DongbuAnam semiconductor Inc.

(21) Appl. No.: 11/317,772

(22) Filed: Dec. 23, 2005

(30) Foreign Application Priority Data
Dec. 27, 2004 (KR) 10-2004-0113331

(51) Int. Cl. C23C 16/00; B08B 7/00

(52) U.S. Cl. 427/248.1; 118/715; 137/15.01

(57) ABSTRACT

The present invention has been made in an effort to provide a CVD apparatus and a method of manufacturing a semiconductor device using the same having advantages of providing a precursor supplying apparatus that can prevent defects and/or contamination by source material-based contaminants that may result from certain operations performed during maintenance work. An exemplary precursor supplying apparatus for a CVD apparatus according to an embodiment of the present invention includes a precursor storage tank, a gas inlet line adapted to flow inert gas into the storage tank, a gas supply line connected to the storage tank and adapted to supply a precursor to a CVD chamber, and a backflow-prevention line connected to the gas inlet line and adapted to flow an inert gas into the storage tank and/or the gas inlet line.

### CROSS-REFERENCE TO RELATED APPLICATION

This application claims priority to and the benefit of Korean Patent Application No. 10-2004-0113331, filed in the Korean Intellectual Property Office on Dec. 27, 2004, the entire contents of which are incorporated herein by reference.

### BACKGROUND OF THE INVENTION

(a) Field of the Invention

The present invention relates to a CVD apparatus and a method of manufacturing a semiconductor device using the same. More particularly, the present invention relates to a precursor supplying apparatus in a CVD apparatus, and an application thereof.

(b) Description of the Related Art

Generally, in a process of manufacturing a semiconductor device, a chemical vapor deposition (CVD) method or physical vapor deposition (PVD) method may be used for depositing various layers, such as a dielectric layer and a metal layer.

Among process gases used in CVD process, some precursors such as tetrakis-dimethylamino titanium (TDMAT; C₈H₂₄N₄Ti) have liquid characteristics at ambient temperatures or other CVD processing temperatures. The precursors having liquid characteristics are supplied to or in a CVD apparatus, they are transferred to the deposition chamber in the gas phase by bubbling an inert gas such as helium gas through the liquid precursor.

A conventional TDMAT supplying apparatus for a CVD process will hereinafter be described in detail with reference to the accompanying drawings.

FIG. 1 is a schematic diagram showing a conventional TDMAT supplying apparatus for a CVD process. As shown, a conventional TDMAT supplying apparatus 10 for a CVD process and chamber has a TDMAT storage tank 11, a gas inlet line 12 for inflowing helium (He) gas thereinto, and a gas supply line 13 for supplying TDMAT into the CVD chamber (not shown). A first manual valve 14 is located on the gas inlet line 12 and a second manual valve 15 is located on the gas supply line 13. In addition, a first automatic valve AV 17 that can be opened and/or closed by a controller 16 is located on the gas inlet line 12, and a second automatic valve AV 18 that can be opened and/or closed by controller 16 is located on the gas supply line 13.

In addition, the storage tank 11 may have a level sensor 19 therein. The level sensor 19 detects a liquid level in the storage tank 11, and sends a level detection signal to the controller 16.

In such a conventional TDMAT supplying apparatus 10 for a CVD process, when the first and the second automatic valve 17 and 18 are opened by the controller 16, the TDMAT stored in the storage tank 11 provides vapor (or a gas phase) that mixes with or is dissolved by helium gas flowed thereinto through the gas inlet line 12, and the gas phase TDMAT and the helium gas are supplied into the CVD chamber through the gas supply line 13. The first and the second manual valve 14 and 15 are operated by manual control in order to prevent helium gas or TDMAT from flowing through the gas inlet line 12 or the gas supply line 13 during maintenance work on the CVD chamber or the TDMAT storage tank.

However, TDMAT (or at least the pressure of TDMAT in a TDMAT storage tank) is very sensitive to temperature, and thus, as the first manual valve 14 is opened after being closed during maintenance work, the vapor pressure of the TDMAT in the storage tank 11 may be increased. According to the pressure difference between the storage tank 11 and the gas inlet line 12, the bubble phase TDMAT and the helium gas in the storage tank 11 may flow backward through the gas inlet line 12. When the TDMAT flows backward into the gas inlet line 12, particles (e.g., so-called “fallout” particles) may be generated therein. The particles may flow into the CVD chamber with the helium gas carrier during a CVD process, so defects that may adversely affect product yield may fall or otherwise be deposited on surfaces of wafers being processed in the CVD chamber.

In addition, a gas inlet line 12 that is contaminated by particles may be difficult to clean and/or re-use, and therefore the apparatus operating rate (or throughput) may decrease and maintenance costs for the CVD apparatus may increase.

The above information disclosed in this Background section is only for enhancement of understanding of the background of the invention, and therefore, it may contain information that does not form prior art or other information that is already known in this or any other country to a person of ordinary skill in the art.

### SUMMARY OF THE INVENTION

The present invention has been made in an effort to provide a CVD apparatus and method of manufacturing a semiconductor device using the same having advantages of providing a precursor supplying apparatus that can reduce or prevent contamination by source material (and/or the CVD precursor) during maintenance work.

An exemplary precursor supplying apparatus for a CVD apparatus according to an embodiment of the present invention includes a precursor storage tank, a gas inlet line adapted to flow an inert gas into the storage tank, a gas supply line connected to the storage tank and adapted to supply a precursor to a CVD chamber, and a backflow-prevention line connected to the gas inlet line and adapted to flow an inert gas into the storage tank (and optionally or alternatively, into the gas inlet line).

In a further embodiment, the exemplary precursor supplying apparatus may further include a first manual valve between the tank and the backflow-prevention line and/or the gas inlet line, a first automatic valve configured to control flow of an inert gas from the gas inlet line, a second manual valve and a second automatic valve on the gas supply line, and/or a third manual valve adapted to control (e.g., by opening and shutting) the flow of the inert gas into the backflow-prevention line. In one implementation, the first automatic valve is interposed between the backflow-prevention line and the gas inlet line.

The first and the second automatic valve may be operated and/or controlled by the controller.

In addition, the exemplary precursor supplying apparatus may further include a check valve for preventing a backflow between the first manual valve and the first automatic valve on the backflow-prevention line and/or the gas inlet line.

Tetrakis-dimethylamino titanium (TDMAT; C₈H₂₄N₄Ti) may be used as an exemplary precursor.

Another exemplary embodiment according to the present invention is a method of performing a deposition process using the CVD apparatus.

In a further embodiment, for depositing a TiN layer, TDMAT may be used as the precursor supplied to the CVD apparatus, and helium may be used as the inert gas supplied to the CVD apparatus.

The TiN layer may function as a diffusion barrier for a metallization structure in a semiconductor device, and the TiN layer may have a thickness of 100-1000 Å.

### BRIEF DESCRIPTION OF THE DRAWINGS

FIG. 1 is a schematic diagram showing a conventional TDMAT supplying apparatus for a CVD process.

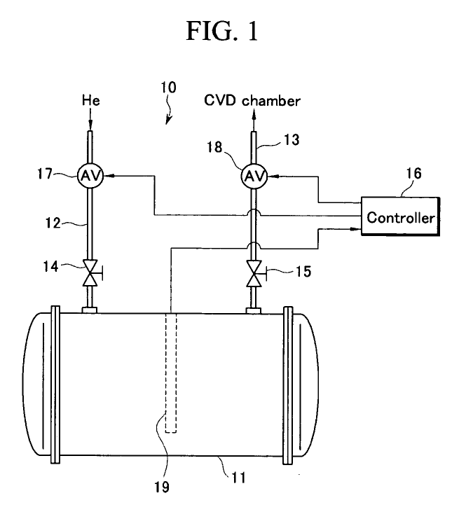

FIG. 2 is a schematic diagram showing an exemplary precursor supplying apparatus for a CVD apparatus according to an embodiment of the present invention.

### DETAILED DESCRIPTION OF THE EMBODIMENTS

An exemplary embodiment of the present invention will hereinafter be described in detail with reference to the accompanying drawings.

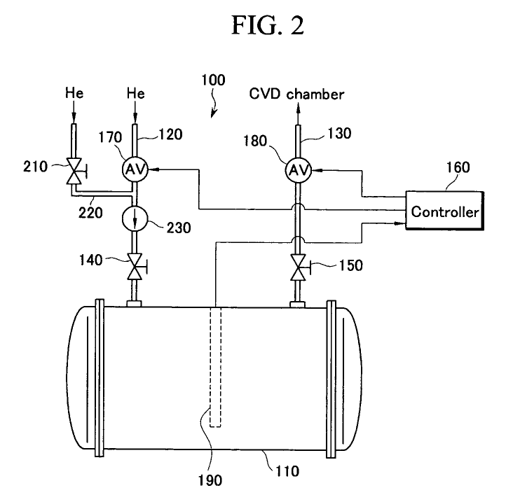

FIG. 2 is a schematic diagram showing an exemplary precursor (e.g., TDMAT for TiN deposition) supplying apparatus for a CVD apparatus according to an embodiment of the present invention. As shown in FIG. 2, the precursor supplying apparatus 100 for a CVD apparatus according to an embodiment of the present invention includes a precursor storage tank 110, a gas inlet line 120 for flowing an inert gas into the storage tank, and a gas supply line 130 that is connected to the storage tank 110 and supplies a precursor to a CVD chamber (not shown). The first manual valve 140 is formed on the gas inlet line 120, and the second manual valve 150 is formed on the gas supply line 130. In addition, the first and second automatic valve 170 and 180 that are opened/closed by a controller 160 are formed on the gas inlet line 120 and the gas supply line 130, respectively. A backflow-preventing line 220 having a third manual valve 210 is formed on the gas inlet line 120.

In the storage tank 110, a precursor such as a TDMAT, tetrakis-diethylaminotitanium (TDEAT; C₁₆H₄₀N₄Ti) or other volatile titanium compound of the formula (RR′N)₄Ti (where R and R′ are independently a C₁-C₆ alkyl group), WF₆, tetraethylorthosilicate (TEOS; C₈H₂₀O₄Si) or other silane compound of the formula (R¹O)₄Si, SiₙH₂ₙ₊₂ or c-SiₘH₂ₘ (where each R¹ is independently a C₁-C₆ alkyl group, n is an integer of from 1 to 4, and m is an integer of from 3 to 8), etc., is stored. A level sensor 190 detects a liquid level in the storage tank 110 and sends a level detection signal to the controller 160. After the controller 160 determines the liquid level in the storage tank 110 by receiving the detection signal from the level sensor 190, the controller 160 opens or closes the first and second automatic valves 170 and 180 so as to control the inert gas flow to the tank 110 and the precursor supply into the CVD chamber.

The gas inlet line 120 provides a path for an inert gas such as helium gas, neon, argon, krypton, etc. When the first manual valve 140 is open and the first automatic valve 170 is opened by the controller 160, the inert gas is supplied from a gas supply part (such as a gas storage tank; not shown) to the storage tank 110. In addition, the gas supply line 130 provides a path for the precursor that is in the gas or vapor phase, carried by the inert (helium) gas. When the second manual valve 150 is open and the second automatic valve 180 is opened by the controller 160, the gas phase precursor and the inert (helium) gas are supplied to the CVD chamber. As is known in the art, the controller 160 can control a flow rate of the precursor-inert gas mixture to the CVD chamber. Also, the tank 110 may further include one or more heating and/or cooling elements for controlling (e.g., increasing and/or decreasing) a concentration or partial pressure of the precursor in the precursor-inert gas mixture.

The backflow-prevention line 220 may be located at least in part between the first manual valve 140 and the first automatic valve 170 (which may be on or which may control an output or flow from the gas inlet line 120). The backflow-prevention line 220 provides a path for helium or other inert gas flowing from an external gas supplying apparatus (such as a gas storage tank) to the gas inlet line 120. In order to control the flow of inert (helium) gas in the backflow-prevention line 220, the third manual valve 210 (which is generally manually opened and shut) is located thereon, typically in a branch (e.g., a T- or Y-section or -joint) of gas inlet also receiving the output of the first automatic valve 170 and/or a check valve 230, and/or providing an input to the check valve 230 and/or the first manual valve 140.

In addition, a check valve 230 may be placed or located in the gas inlet line 120 and/or backflow-prevention line 220 to prevent a backflow of the precursor from the storage tank 110, particularly when the pressure in the storage tank 110 is greater than the pressure in the gas inlet line 120 and/or backflow-prevention line 220. For example, the check valve 230 may be placed or located between the first manual valve 140 and the first automatic valve 170 on or in the gas inlet line 120, and/or between the first manual valve 140 and the third manual valve 210 in the backflow-prevention line 220.

The precursor supplying apparatus for a CVD apparatus having such a structure as described above is operated as follows.

The gas inlet line 120 and the gas supply line 130 are closed by closing the first and second manual valve 140 and 150 during or prior to maintenance work, effectively isolating the precursor tank 110. As the first manual valve 140 is opened thereafter, the pressure of the gas phase precursor in the storage tank 110 may be higher than the pressure in the gas inlet line 120 (and/or in the backflow-prevention line 220). In such a case, the gas phase precursor (e.g., TDMAT) and the inert (e.g., helium) gas in the storage tank 110 may flow backward into the gas inlet line 120 (and/or into the backflow-prevention line 220). During the maintenance work (or at least prior to opening the first manual valve 140), the third manual valve 210 may be opened to supply an inert (e.g., helium) gas to the gas inlet line 120 (and/or the backflow-prevention line 220) between the first manual valve 140 and the first automatic valve 170. In one embodiment, the pressure of the inert gas introduced through the third manual valve 210 into the gas inlet line 120 and/or the backflow-prevention line 220 is greater than the pressure of the precursor vapor-inert gas mixture in the precursor tank 110. Thus, a precursor backflow into the gas inlet line 120 (and, optionally, the backflow-prevention line 220) can be inhibited or prevented. In addition, the check valve 230 on the gas inlet line 120 may also or may further reduce, inhibit or prevent the precursor backflow into the gas inlet line 120 and (optionally) the backflow-prevention line 220.

Therefore, the precursor backflow to the gas inlet line 120 from the storage tank 110 caused by a pressure difference therebetween during maintenance work can be reduced, inhibited or prevented, and thus generation of particles in the gas inlet line 120 by precursor contamination can be reduced, inhibited or prevented. Consequently, a flow of fallout particles into the CVD chamber during a CVD process can be prevented, and therefore defects on wafers can be suppressed and product yield can be increased. In addition, a decrease in the apparatus operating rate or time (e.g., operating efficiency) and an increase in maintenance costs that may be caused by contamination of the gas inlet line 120 can be reduced, inhibited or prevented.

The CVD apparatus improved by an exemplary embodiment of the present invention can be used for forming a TiN layer as a diffusion barrier layer in a metallization process. When the TiN layer that is formed by using the exemplary CVD apparatus is deposited to a thickness of 100-1000 Å, it may have good uniformity and be substantially defect-free.

The present invention has been made in order to solve problems in applying TDMAT as a precursor for TiN metal organic CVD (MOCVD), but it can also apply to other CVD apparatuses using a bubble method (e.g., where an inert gas is bubbled through a liquid phase precursor in a precursor storage tank). A CVD method such as MOCVD has an advantage in step-coverage characteristics, and thus it can be effectively used for depositing diffusion barrier layers in metallization processes for semiconductor devices.

As described above, the precursor supplying apparatus for a CVD apparatus according to the present invention can increase the pressure in the gas inlet line that provides an inert gas into the precursor storage tank, so it can prevent the precursor from flowing back into the gas inlet line from the storage tank. Consequently, a flow of fallout particles to the CVD chamber during a CVD process can be reduced, inhibited or prevented, and therefore defects on wafers can be reduced or suppressed and product yield can be increased.

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. A CVD apparatus, comprising:
a precursor storage tank;
a gas inlet line adapted to flow an inert gas into the storage tank;
a gas supply line connected to the storage tank and adapted to supply a precursor to a CVD chamber; and
a backflow-prevention line connected to the gas inlet line and adapted to flow inert gas into the storage tank.

2. The CVD apparatus of claim 1, further comprising:
a first manual valve between the storage tank and the gas inlet line and/or the backflow-prevention line; and
a first automatic valve interposed in the gas inlet line or between the gas inlet line and the backflow-prevention line.

3. The CVD apparatus of claim 1, further comprising:
a second manual valve and a second automatic valve located on or in the gas supply line,

4. The CVD apparatus of claim 1, further comprising:
a third manual valve adapted to control the flow of the inert gas into the backflow-prevention line.

5. The CVD apparatus of claim 2, further comprising a check valve configured to prevent a backflow of precursor vapor into the gas inlet line and/or the backflow-prevention line.

6. The CVD apparatus of claim 1, wherein the precursor comprises tetrakis-dimethylaminotitanium (TDMAT; C₈H₂₄N₄Ti).

7. The CVD apparatus of claim 1, wherein the inert gas comprises helium (He) gas.

8. The CVD apparatus of claim 2, further comprising a controller configured to operate the first and the second automatic valves.

9. The CVD apparatus of claim 1, further comprising the CVD chamber.

10. The CVD apparatus of claim 1,wherein the backflow-prevention line is further adapted to flow inert gas into the gas inlet line.

11. A method of manufacturing a semiconductor device, comprising:
preparing a CVD apparatus having a precursor supplying apparatus therein, the precursor supplying apparatus comprising a precursor storage tank, a gas inlet line adapted to flow an inert gas into the storage tank, a gas supply line connected to the storage tank and adapted to supply a precursor to a CVD chamber, and a backflow-prevention line connected to the gas inlet line and adapted to flow an inert gas into the storage tank; and
performing a deposition process using the CVD apparatus.

12. The method of claim 11, wherein the precursor supplying apparatus further comprises:
a first manual valve between the storage tank and the gas inlet line and/or the backflow-prevention line, and a first automatic valve interposed in the gas inlet line or between the backflow-prevention line and the gas inlet line;
a second manual valve and a second automatic valve located on or in the gas supply line; and
a third manual valve adapted to control the flow of the inert gas into the backflow-preventing line.

13. The method of claim 11, wherein the precursor supplying apparatus further comprises a check valve configured to prevent a backflow of precursor vapor into the gas inlet line and/or the backflow-prevention line.

14. The method of claim 12, further comprising operating the first and the second automatic valves with a controller.

15. The method of claim 11, further comprising depositing a TiN layer by supplying TDMAT as the precursor to the CVD apparatus.

16. The method of claim 11, wherein the inert gas that is supplied to the CVD apparatus comprises helium.

17. The method of claim 15, further comprising forming a metallization layer on the TiN layer, wherein the TiN layer functions as a diffusion barrier.

18. The method of claim 15, wherein the TiN layer has a thickness of 100-1000 Å.

19. A method of maintaining a CVD apparatus, comprising:
closing first and second valves, respectively between (1) an inert gas inlet line and a precursor supply tank, and (2) the precursor supply tank and a CVD chamber of the apparatus;
performing maintenance on the CVD apparatus;
opening a third valve between an inert gas supply and a backflow-prevention line to inhibit or prevent a backflow of precursor vapor from the precursor supply tank into the inert gas inlet line; and
opening the first and second valves.

20. The method of claim 19, wherein the inert gas introduced through the third valve has a pressure greater than a pressure of a precursor vapor-inert gas mixture in the precursor supply tank.
